(19) United States
(12) Patent Application Publication
(10) Pub. No.: US 2022/0320417 A1
(43) Pub. Date: Oct. 6, 2022

(54) METHOD OF MANUFACTURING ALUMINUM NITRIDE FILMS

(71) Applicant: Applied Materials, Inc., Santa Clara, CA (US)

(72) Inventors: Abhijeet Laxman Sangle, Maharashtra (IN); Suresh Chand Seth, Mumbai (IN); Vijay Bhan Sharma, Rajasthan (IN); Bharatwaj Ramakrishnan, San Jose, CA (US); Ankur Anant Kadam, Thane (IN)

(73) Assignee: Applied Materials, Inc., Santa Clara, CA (US)

(21) Appl. No.: 17/220,136

(22) Filed: Apr. 1, 2021

(51) Int. Cl. H01L 41/316; H01L 41/18; H01L 41/29

(52) U.S. Cl. CPC H01L 41/316; H01L 41/18; H01L 41/29

(57) ABSTRACT

Doped-aluminum nitride (doped-AlN) films and methods of manufacturing doped-AlN films are disclosed. Some methods comprise forming alternating pinning layers and doped-AlN layers including a dopant selected from the group consisting of Sc, Y, Hf, Mg, Zr and Cr, wherein the pinning layers pin the doped-AlN layers to a c-axis orientation. Some methods include forming a conducting layer including a material selected from the group consisting of Mo, Pt, Ta, Ru, LaNiO₃ and SrRuO₃. Some methods include forming a thermal oxide layer having silicon oxide on a silicon substrate. Piezoelectric devices comprising the doped-AlN film are also disclosed.

### TECHNICAL FIELD

Embodiments of the disclosure generally relate to films and methods of manufacturing films (e.g., aluminum nitride films) and piezoelectric devices comprising such films. In particular, embodiments of the disclosure relate to films comprising alternating pinning layers and doped aluminum nitride (doped-AlN) layers and methods of manufacturing films and piezoelectric devices comprising forming alternating pinning layers and doped-AlN layers.

### BACKGROUND

Films such as aluminum nitride films, in particular, doped aluminum nitride films, have a tendency to develop conical defects, for example as such films are grown to greater thicknesses. Conical defects have a crystalline orientation other than a c-axis orientation. Thus, a crystalline orientation other than a c-axis orientation may result in a film or piezoelectric device with a higher concentration of conical defects. Such conical defects may also be referred to as exhibiting misoriented or abnormally oriented grains, referring to the fact that the grains have a crystalline orientation other than a c-axis orientation. Conical defects in films can have problematic implications in radio frequency (RF) filters, actuators and microphones and may negatively impact 5G technologies and communications.

Conventional techniques used to address the formation of conical defects exhibiting abnormally oriented grains (AOGs) involve process-tuning such as tuning gas ratios, temperature and RF bias during deposition of the films. However, these techniques are not completely effective in significantly reducing the occurrence of conical defects. Specific limitations of the conventional techniques include process drift, deposition tool-to-deposition tool non-uniformity, and reproducibility challenges. As the thickness of such films is increased, the ability of a bottom electrode lattice to pin doped-AlN layers to the same orientation becomes limited. The inability of a bottom electrode lattice to pin doped-AlN layers may result in relaxation of stress by forming dislocations. Relaxation of stress is also potentially problematic as this may cause the doped-AlN layers and grains on the doped-AlN layers to have a crystalline orientation other than c-axis orientation. Conical defects, including AOGs grow at a faster rate than c-axis oriented grains, and thus, the size of AOGs and number of AOGs increase. Thus, a crystalline orientation other than c-axis orientation may result in a film with a higher concentration of conical defects, including AOGs. Conical defects may be responsible for degradation of piezoelectric performance and greater dielectric loss.

Accordingly, there is a need for films including aluminum nitride and methods of manufacturing such films and piezoelectric devices in which conical defects exhibiting AOGs are minimized.

### SUMMARY

One or more embodiments of the disclosure are directed to a film on a substrate, the film comprising alternating pinning layers and doped-AlN layers including a dopant selected from the group consisting of Sc, Y, Hf, Mg, Zr and Cr, wherein the pinning layers pin the doped-AlN layers to a c-axis orientation.

Additional embodiments of the disclosure are directed to a piezoelectric device comprising a film on a substrate, the film comprising alternating pinning layers and doped-AlN layers including a dopant selected from the group consisting of Sc, Y, Hf, Mg, Zr and Cr, wherein the pinning layers pin the doped-AlN layers to a c-axis orientation.

Further embodiments of the disclosure are directed to a method of manufacturing a film, the method comprising forming on a substrate alternating pinning layers and doped-AlN layers including a dopant selected from the group consisting of Sc, Y, Hf, Mg, Zr and Cr, wherein the pinning layers pin the doped-AlN layers to a c-axis orientation.

One or more embodiments of the disclosure are directed to a method of manufacturing a piezoelectric device comprising forming a conducting layer including a material selected from the group consisting of Mo, Pt, Ta, Ru, LaNiO₃ and SrRuO₃, and forming alternating pinning layers and doped-AlN layers including a dopant selected from the group consisting of Sc, Y, Hf, Mg, Zr and Cr, wherein the pinning layers pin the doped-AlN layers to a c-axis orientation.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates alternating pinning layers and doped-AlN layers according to one or more embodiments;

FIG. 2 illustrates a flow diagram of a method of manufacturing a film according to one or more embodiments;

FIG. 3 illustrates a flow diagram of a method of manufacturing a piezoelectric device according to one or more embodiments;

FIG. 4 illustrates a first embodiment of a piezoelectric device;

FIG. 5 illustrates a second embodiment of a piezoelectric device; and

FIG. 6 illustrates a third embodiment of a piezoelectric device.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used in this specification and appended claims, the terms “cone defects” or “conical defects” refer to defects including misoriented grains or abnormally oriented grains (AOGs) with a crystalline orientation other than a c-axis orientation. All crystalline materials are classified into one of seven crystal systems, based on their symmetry. In crystal drawings, by convention, the c-axis usually is orientated vertically, in the plane of the paper. All crystalline material and crystals except those in the cubic (or isometric) crystal system have a c-axis. Wurtzite AlN comprises two hexagonal close-packed lattices, one with Al and another with N atoms that displaced from each other vertically. Each Al atom is bonded tetrahedrally to four N atoms and vice versa. The structure can be described by the lattice constant c, which is the height of the cell, the lattice constant a, which is the edge length of the base, and u, which is the bond length between the Al and N atoms expressed in units of c. According to one or more embodiments, aluminum nitride films are provided that have a reduced incidence of misoriented or abnormally oriented grains that have a crystalline orientation other than a c-axis orientation. Advantageously, in one or more embodiments, aluminum nitride films are provided that exhibit a high number of grains exhibiting a c-axis orientation.

In one or more embodiments, a film is formed by deposition techniques, such as but not limited to physical vapor deposition (PVD), chemical vapor deposition (CVD), plasma-enhanced chemical vapor deposition (PECVD), metalorganic chemical vapor deposition (MOCVD), molecular beam epitaxy (MBE), atomic layer deposition (ALD), plasma-enhanced atomic layer deposition (PEALD), spin-on, or other deposition techniques known to one of ordinary skill in the art of microelectronic device manufacturing. In one or more embodiments, the film is formed by PVD.

In one or more embodiments, a film is formed in a processing chamber. The processing chamber can be any suitable processing chamber known to the skilled artisan including, but not limited to, a PVD chamber, a CVD chamber, a PECVD chamber, a MOCVD chamber, an MBE chamber, an ALD chamber, or a PEALD chamber. In one or more embodiments, the film is formed in the PVD chamber.

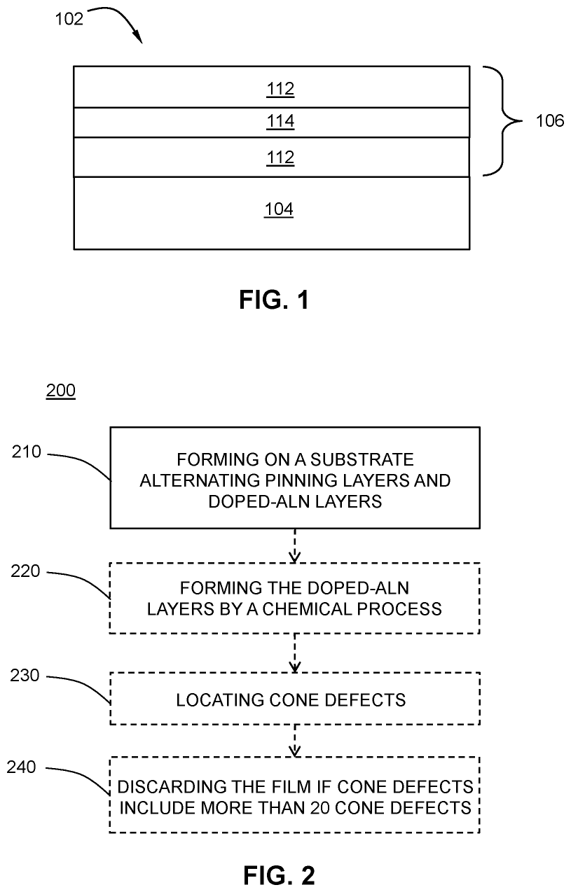

Referring now to FIG. 1, an embodiment of a film 102 on a substrate 104 is illustrated. The film 102 comprises alternating pinning layers and doped-AlN layers 106 including a dopant selected from the group consisting of Sc, Y, Hf, Mg, Zr and Cr, wherein the pinning layers 114 pin the doped-AlN layers 112 to a c-axis orientation. The alternating pinning layers and doped-AlN layers 106 include a pinning layer 112 on a substrate 104 and a doped-AlN layer 114 on the pinning layer 112 which continue to alternate and may include up to 1000 alternating pinning layers and doped-AlN layers 106.

In one or more embodiments, the pinning layers 114 comprise AlN. In one or more embodiments, the pinning layers 114 have a thickness and the doped-AlN layers 112 have a thickness, and the thickness of the pinning layers 114 is less than the thickness of the doped-AlN layers 112. In one or more embodiments, the thickness of the pinning layers 114 is in a range of from about 2 nm to about 20 nm, from about 5 nm to about 12 nm and from about 8 nm to about 10 nm. In one or more embodiments, the thickness of the doped-AlN layers 112 is in a range from about 10 nm to about 200 nm, from about 40 nm to about 150 nm and from about 70 nm to about 120 nm.

Films 102 typically develop conical defects, in particular AlN films that have a relatively large thickness. Conical defects have a crystalline orientation other than a c-axis orientation. Thus, a crystalline orientation other than a c-axis orientation may result in a film 102 with a higher concentration of conical defects. For example, conical defects may develop once a film 102 is in a range from about 60 nm to about 150 nm thick or thicker.

In one or more embodiments, a c-axis orientation of grains of a crystalline film is determined by x-ray diffraction (XRD) or transmission electron microscopy (TEM). XRD is an analytical technique primarily used for phase identification of a crystalline material. TEM is a microscopy technique in which a beam of electrons is transmitted through a specimen to form an image. The value of full width at half maximum (FWHM) is a parameter used to describe the width of a “bump” on a curve or function. Specifically, the value of FWHM describes the degree of crystallinity. The value of FWHM of a rocking curve peak or the value of FWHM of rocking curve is a relative measure of c-axis orientation. As an example, the smaller the value of FWHM of rocking curve, the better the c-axis orientation and degree of crystallinity. In one or more embodiments, the c-axis orientation of film 102 has a value of FWHM of rocking curve that is less than 2 degrees, less than 1.5 degrees or less than 1 degrees.

Referring now to FIG. 2, a flow diagram of an exemplary embodiment of a method of manufacturing a film is shown. The method 200 comprises at operation 210 forming on a substrate alternating pinning layers and doped-AlN layers including a dopant selected from the group consisting of Sc, Y, Hf, Mg, Zr and Cr, wherein the pinning layers pin the doped-AlN layers to a c-axis orientation. In one or more embodiments, the method 200 optionally includes at operation 220 forming the doped-AlN layers by a chemical process selected from the group consisting of PVD, MBE, CVD, PECVD, MOCVD, PLD, ALD and PEALD. In one or more embodiments, the method 200 optionally includes at operation 230 locating cone defects in the doped-AlN layers by scanning electron microscopy (SEM) or TEM. SEM is a microscopy technique which uses a focused beam of high-energy electrons to generate a variety of signals at the surface of a solid specimen. Films typically develop cone defects including AOGs, if at all, as the film is grown thicker. For example, AOGs may develop once a film is in a range from about 60 nm to about 150 nm thick or thicker. In one or more embodiments, the method 200 optionally includes at operation 240 discarding the film if the cone defects include more than 20 cone defects, wherein each of the more than 20 cone defects has a size of greater than about 2 μm in a 10×10 μm² area.

In one or more embodiments, the pinning layers and the doped-AlN layers have lattice parameters that are identical.

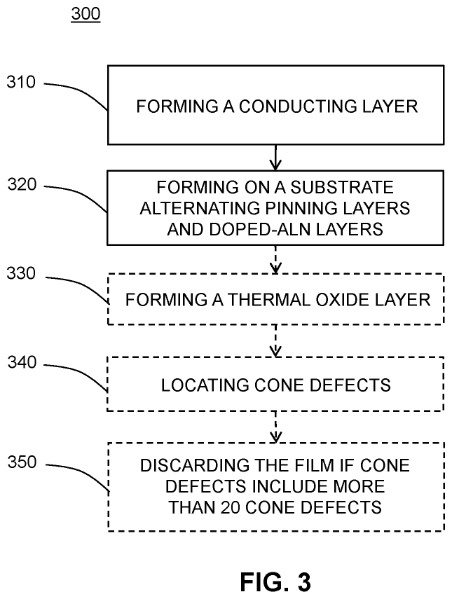

Referring to FIG. 3, a flow diagram of an embodiment of a method of manufacturing a piezoelectric device is shown. The method 300 comprises at operation 310 forming a conducting layer including a material selected from the group consisting of Mo, Pt, Ta, Ru, LaNiO₃ and SrRuO₃. In one or more embodiments, the conducting layer is formed on a substrate. The conducting layer may also be referred to as an electrode, a top electrode or bottom electrode. In one or more embodiments, the conducting layer has a thickness in a range from about 10 nm to about 200 nm. The method 300 comprises at operation 320 forming alternating pinning layers and doped-AlN layers including a dopant selected from the group consisting of Sc, Y, Hf, Mg, Zr and Cr, wherein the pinning layers pin the doped-AlN layers to a c-axis orientation. In one or more embodiments, the alternating pinning layers and doped-AlN layers include a pinning layer on a substrate and a doped-AlN layer on the pinning layer which continue to alternate and may include up to 1000 alternating pinning layers and doped-AlN layers. In one or more embodiments, a first conducting layer is formed on a substrate and a second conducting layer is formed on the alternating pinning layers and doped-AlN layers.

In one or more embodiments, the pinning layers comprise AlN. In one or more embodiments, the pinning layers have a thickness and the doped-AlN layers have a thickness, and the thickness of the pinning layers is less than the thickness of the doped-AlN layers. In one or more embodiments, the thickness of the pinning layers is in a range of from about 2 nm to about 20 nm, from about 5 nm to about 12 nm and from about 8 nm to about 10 nm. In one or more embodiments, the thickness of the doped-AlN layers is in a range from about 10 nm to about 200 nm, from about 40 nm to about 150 nm and from about 70 nm to about 120 nm.

The method 300 optionally includes at operation 330 forming a thermal oxide layer having silicon oxide on a silicon substrate. In one or more embodiments, forming 330 the thermal oxide layer includes a process of thermal evaporation or PECVD. In one or more embodiments, the thermal oxide layer has a thickness in a range from about 10 nm to about 1000 nm. In one or more embodiments, the thermal oxide layer is formed on the silicon substrate. In one or more embodiments, a first conducting layer is formed on a silicon substrate and a second conducting layer is formed on the alternating pinning layers and doped-AlN layers. In one or more embodiments, the thermal oxide layer is formed on the first conducting layer. In one or more embodiments, the thermal oxide layer is formed on the second conducting layer. In one or more embodiments, the thermal oxide layer is formed on the first conducting layer and the second conducting layer.

In one or more embodiments, the method 300 optionally includes at operation 340 locating cone defects in the doped-AlN layers by SEM or TEM. Films typically develop cone defects including AOGs, if at all, as the film is grown thicker. For example, AOGs may develop once a film is in a range from about 60 nm to about 150 nm thick or thicker.

In some embodiments, c-axis elongation of AlN unit cells by doping permits greater electromechanical response in doped-AlN lattice for the same magnitude of electric field applied. In some embodiments, for the initial few 10s of nm of doped-AlN layers grown on a conducting layer (bottom electrode) including a material selected from the group consisting of Mo, Pt, Ta, Ru, LaNiO₃ and SrRuO₃, the doped-AlN layers in-plane lattice parameters are matched closely with that of the bottom electrode in order to minimize interfacial energy by attaining (hetero)epitaxy. Matching the doped-AlN layers in-plane lattice parameters helps in in-plane compression of doped-AlN lattice, leading to c-axis elongation. The resultant grains have dominant c-axis orientation and compressive strain, both of which are favorable to achieve high piezoelectric performance.

In one or more embodiments, the method 300 optionally includes at operation 350 discarding the film if the cone defects include more than 20 cone defects, wherein each of the more than 20 cone defects has a size of greater than about 2 μm in a 10×10 μm² area.

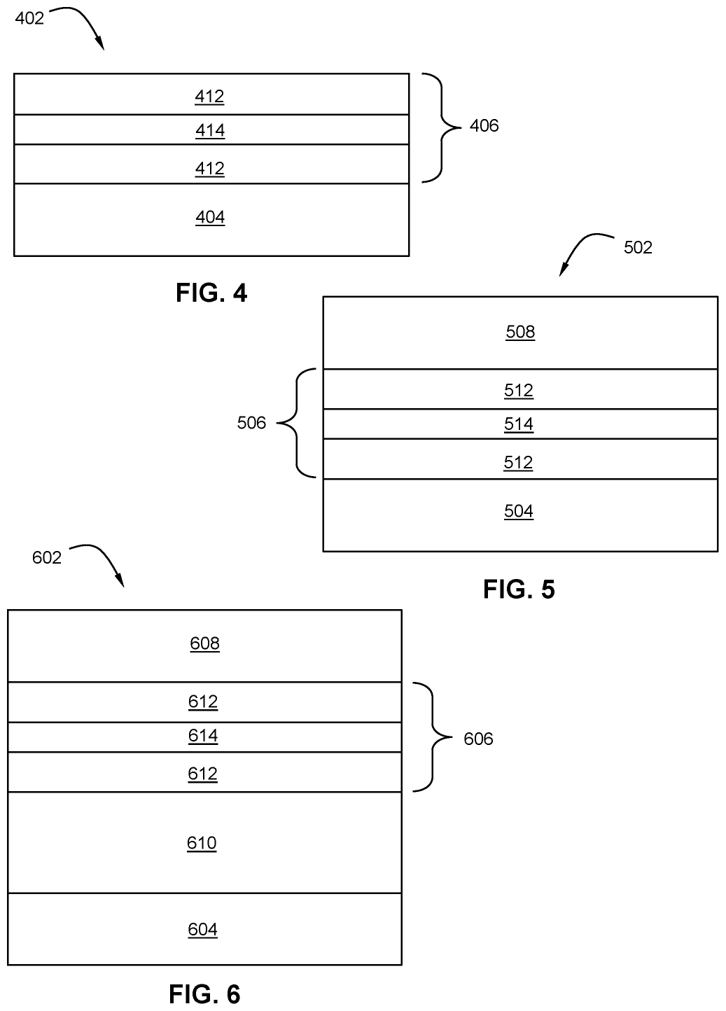

Referring to FIG. 4, a first embodiment of a piezoelectric device 402 is shown. The piezoelectric device 402 comprises alternating pinning layers and doped-AlN layers 406 including a dopant selected from the group consisting of Sc, Y, Hf, Mg, Zr and Cr, wherein the pinning layers 414 pin the doped-AlN layers 412 to a c-axis orientation. The alternating pinning layers and doped-AlN layers 406 include a pinning layer 414 on a substrate 404 and a doped-AlN layer 412 on the pinning layer 414 which continue to alternate and may include up to 1000 alternating pinning layers and doped-AlN layers 406.

In one or more embodiments, the pinning layers 414 comprise AlN. In one or more embodiments, the pinning layers 414 have a thickness and the doped-AlN layers 412 have a thickness, and the thickness of the pinning layers 414 is less than the thickness of the doped-AlN layers 412. In one or more embodiments, the thickness of the pinning layers 414 is in a range of from about 2 nm to about 20 nm, from about 5 nm to about 12 nm and from about 8 nm to about 10 nm. In one or more embodiments, the thickness of the doped-AlN layers 412 is in a range from about 10 nm to about 200 nm, from about 40 nm to about 150 nm and from about 70 nm to about 120 nm.

In one or more embodiments, the c-axis orientation of the piezoelectric device 402 has a value of FWHM of rocking curve that is less than 2 degrees, less than 1.5 degrees or less than 1 degrees.

Referring to FIG. 5, a second embodiment of a piezoelectric device 502 is shown. The piezoelectric device 502 comprises alternating pinning layers and doped-AlN layers 506 including a dopant selected from the group consisting of Sc, Y, Hf, Mg, Zr and Cr, wherein the pinning layers 514 pin the doped-AlN layers 512 to a c-axis orientation. The alternating pinning layers and doped-AlN layers 506 include a pinning layer 514 on a substrate 504 and a doped-AlN layer 512 on the pinning layer 514 which continue to alternate and may include up to 1000 alternating pinning layers and doped-AlN layers 506.

In one or more embodiments, the pinning layers 514 comprise AlN. In one or more embodiments, the pinning layers 514 have a thickness and the doped-AlN layers 512 have a thickness, and the thickness of the pinning layers 514 is less than the thickness of the doped-AlN layers 512. In one or more embodiments, the thickness of the pinning layers 514 is in a range of from about 2 nm to about 20 nm, from about 5 nm to about 12 nm and from about 8 nm to about 10 nm. In one or more embodiments, the thickness of the doped-AlN layers 512 is in a range from about 10 nm to about 200 nm, from about 40 nm to about 150 nm and from about 70 nm to about 120 nm. The alternating pinning layers and doped-AlN layers 506 include a pinning layer 512 on a substrate 504 and a doped-AlN layer 512 on the pinning layer 514 which continue to alternate and may include up to 1000 alternating pinning layers and doped-AlN layers 506.

Referring still to FIG. 5, the second embodiment of the piezoelectric device 502 may include a conducting layer 508. In one or more embodiments, the conducting layer 508 includes a material selected from the group consisting of Mo, Pt, Ta, Ru, LaNiO₃ and SrRuO₃. In one or more embodiments, the conducting layer 508 is formed on a substrate 504. The conducting layer 508 may also be referred to as an electrode, a top electrode or bottom electrode. In one or more embodiments, the conducting layer 508 has a thickness in a range from about 10 nm to about 200 nm. In one or more embodiments, a first conducting layer 508 is formed on a substrate 504 and a second conducting layer 508 is formed on the alternating pinning layers and doped-AlN layers 506.

In some embodiments, for the initial few 10s of nm of doped-AlN layers 512 grown on a conducting layer 508 (bottom electrode) including a material selected from the group consisting of Mo, Pt, Ta, Ru, LaNiO₃ and SrRuO₃, the doped-AlN layers 512 in-plane lattice parameters are matched closely with that of the bottom electrode in order to minimize interfacial energy by attaining (hetero)epitaxy. Matching the doped-AlN layers 512 in-plane lattice parameters helps in in-plane compression of doped-AlN lattice, leading to c-axis elongation. The resultant grains have dominant c-axis orientation and compressive strain, both of which are favorable to achieve high piezoelectric performance.

Referring to FIG. 6, a third embodiment of a piezoelectric device 600 is shown. The piezoelectric device 600 comprises alternating pinning layers and doped-AlN layers 606 including a dopant selected from the group consisting of Sc, Y, Hf, Mg, Zr and Cr, wherein the pinning layers 614 pin the doped-AlN layers 612 to a c-axis orientation. The alternating pinning layers and doped-AlN layers 606 include a pinning layer 614 on a substrate 604 and a doped-AlN layer 612 on the pinning layer 614 which continue to alternate and may include up to 1000 alternating pinning layers and doped-AlN layers 606.

In one or more embodiments, the pinning layers 614 comprise AlN. In one or more embodiments, the pinning layers 614 have a thickness and the doped-AlN layers 612 have a thickness, and the thickness of the pinning layers 614 is less than the thickness of the doped-AlN layers 612. In one or more embodiments, the thickness of the pinning layers 614 is in a range of from about 2 nm to about 20 nm, from about 5 nm to about 12 nm and from about 8 nm to about 10 nm. In one or more embodiments, the thickness of the doped-AlN layers 612 is in a range from about 10 nm to about 200 nm, from about 40 nm to about 150 nm and from about 70 nm to about 120 nm.

Referring still to FIG. 6, the third embodiment of the piezoelectric device 600 may include a conducting layer 608. In one or more embodiments, the conducting layer 608 includes a material selected from the group consisting of Mo, Pt, Ta, Ru, LaNiO₃ and SrRuO₃. In one or more embodiments, the conducting layer 608 is formed on a substrate 604. In one or more embodiments, the conducting layer 608 is formed on the alternating pinning layers and doped-AlN layers 606. The conducting layer 608 may also be referred to as an electrode, a top electrode or bottom electrode. In one or more embodiments, the conducting layer 608 has a thickness in a range from about 10 nm to about 200 nm. In one or more embodiments, a first conducting layer 608 is formed on a substrate 604 and a second conducting layer 608 is formed on the alternating pinning layers and doped-AlN layers 606.

Referring still to FIG. 6, the third embodiment of the piezoelectric device may include a thermal oxide layer 610 having silicon oxide on a silicon substrate. In one or more embodiments, the thermal oxide layer 610 is formed by a process of thermal evaporation or PECVD. In one or more embodiments, the thermal oxide layer 610 has a thickness in a range from about 10 nm to about 1000 nm. In one or more embodiments, the thermal oxide layer 610 is formed on the substrate 604. In one or more embodiments, a first conducting layer 608 is formed on a substrate 604 and a second conducting layer 604 is formed on the alternating pinning layers and doped-AlN layers 606. In one or more embodiments, the thermal oxide layer 610 is formed on the first conducting layer 608. In one or more embodiments, the thermal oxide layer 610 is formed on the second conducting layer 608. In one or more embodiments, the thermal oxide layer 610 is formed on the first conducting layer 608 and the second conducting layer 608.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A film on a substrate, the film comprising:
alternating pinning layers and doped-AlN layers including a dopant selected from the group consisting of Sc, Y, Hf, Mg, Zr and Cr, wherein the pinning layers pin the doped-AlN layers to a c-axis orientation.

2. The film of claim 1, wherein the pinning layers comprise AlN.

3. The film of claim 1, wherein the pinning layers have a thickness and the doped-AlN layers have a thickness, and the thickness of the pinning layers is less than the thickness of the doped-AlN layers.

4. The film of claim 3, wherein the thickness of the pinning layers is in a range of from about 2 nm to about 20 nm.

5. The film of claim 3, wherein the thickness of the doped-AlN layers is in a range from about 10 nm to about 200 nm.

6. The film of claim 1, wherein the c-axis orientation has a value of FWHM of rocking curve that is less than 2 degrees.

7. A piezoelectric device comprising the film on the substrate of claim 1.

8. A method of manufacturing a film, the method comprising:
forming on a substrate alternating pinning layers and doped-AlN layers including a dopant selected from the group consisting of Sc, Y, Hf, Mg, Zr and Cr, wherein the pinning layers pin the doped-AlN layers to a c-axis orientation.

9. The method of claim 8, wherein the pinning layers comprise AlN.

10. The method of claim 8, wherein a thickness of the pinning layers is in a range of from about 2 nm to about 20 nm.

11. The method of claim 8, wherein forming the doped-AlN layers includes a process selected from the group consisting of PVD, MBE, CVD, PECVD, MOCVD, PLD, ALD and PEALD.

12. The method of claim 8, wherein the doped-AlN layers have a thickness in a range from about 10 nm to about 200 nm.

13. The method of claim 8, further comprising a process of SEM or TEM to locate cone defects in the doped-AlN layers.

14. The method of claim 13, further comprising discarding the film if the cone defects include more than 20 cone defects, wherein each of the more than 20 cone defects has a size of greater than about 2 μm in a 10×10 μm² area.

15. The method of claim 8, wherein the pinning layers and the doped-AlN layers have lattice parameters that are identical.

16. A method of manufacturing a piezoelectric device, the method comprising:
forming a conducting layer including a material selected from the group consisting of Mo, Pt, Ta, Ru, LaNiO₃ and SrRuO₃; and
forming alternating pinning layers and doped-AlN layers including a dopant selected from the group consisting of Sc, Y, Hf, Mg, Zr and Cr, wherein the pinning layers pin the doped-AlN layers to a c-axis orientation.

17. The method of claim 16, wherein the conducting layer has a thickness in a range from about 10 nm to about 200 nm.

18. The method of claim 16, further comprising forming a thermal oxide layer having silicon oxide on a silicon substrate.

19. The method of claim 18, wherein forming the thermal oxide layer includes a process of thermal oxidation or PECVD.

20. The method of claim 18, wherein the thermal oxide layer has a thickness in a range from about 10 nm to about 1000 nm.
